(19) United States
(12) Patent Application Publication
(10) Pub. No.: US 2026/0251742 A1
(43) Pub. Date: Aug. 27, 2026

(54) COMPUTER-IMPLEMENTED METHOD FOR OPERATING A MAGNETIC RESONANCE FACILITY, MAGNETIC RESONANCE FACILITY, COMPUTER PROGRAM, AND ELECTRONICALLY READABLE DATA CARRIER

(71) Applicant: Siemens Healthineers AG, Forchheim (DE)

(72) Inventor: Mario Zeller, Erlangen (DE)

(21) Appl. No.: 19/546,354

(22) Filed: Feb. 21, 2026

(30) Foreign Application Priority Data
Feb. 21, 2025 (DE) 10 2025 106 730.9

(51) Int. Cl. G01R 33/48; G01R 33/56

(52) U.S. Cl. CPC G01R 33/4818; G01R 33/5608

(57) ABSTRACT

A method for operating a magnetic resonance facility includes, in each readout module, using at least one navigator submodule to acquire navigator data of a sequence segment along a k-space trajectory. For at least one pair of navigator submodules, the k-space trajectory used therein runs at least partially along at least one phase-encoding direction of the acquisition process. For each sequence segment, correlation information is ascertained by comparing the navigator dataset of the sequence segment with at least one navigator dataset of a further sequence segment and the same k-space trajectory. The correlation information is evaluated in order to select sequence segments the magnetic resonance data of which is discarded, and/or to assign a weighting to the magnetic resonance data of at least some of the sequence segments prior to reconstruction of a magnetic resonance image.

This application claims the benefit of German Patent Application No. DE 10 2025 106 730.9, filed on Feb. 21, 2025, which is hereby incorporated by reference in its entirety.

### BACKGROUND

The present embodiments relate to a computer-implemented method for operating a magnetic resonance facility, a magnetic resonance facility, a computer program, and an electronically readable data carrier.

Magnetic resonance imaging is now a frequently used diagnostic and monitoring tool in medical applications. The prolonged acquisition time of conventional acquisition protocols for magnetic resonance data provides that motion is a key issue in improving image quality, because, even when corrected, motion during the acquisition period may lead to a loss of image quality and hence also of the usability of the magnetic resonance data and magnetic resonance images/image datasets reconstructed therefrom. Herein, motion during acquisition from a patient relates to both cyclical motion processes (e.g., respiration and heartbeat) in the living object under examination and other, voluntary and involuntary, externally and internally initiated motion processes in the acquisition region.

Avoiding or taking account of motion has been found to be particularly relevant in TSE sequences (turbo spin echo sequences, also known as RARE sequences or FSE sequences). In a TSE sequence, a radiofrequency excitation pulse in a preparation module is followed by an echo train in a readout module in which, in a plurality of readout submodules, respective readout periods in each case adjoin respective radiofrequency refocusing pulses. The readout periods all benefit from the same radiofrequency excitation pulse. This results in acquisition periods of several minutes in the case of a plurality of echo trains. Nevertheless, the merits of the TSE sequence provide that it is deployed as the “workhorse” of medical imaging. Motion is likewise relevant in other similarly structured sequence types (e.g., in diffusion imaging with gradient echo (GRE) readout in which a preparation module with diffusion gradients is followed by a readout module), in which in each case a readout period follows a radiofrequency excitation pulse in respective readout submodules of a readout module.

In order to be able to work with less magnetic resonance data and hence shorten the acquisition period, trained reconstruction algorithms have been provided that directly use the magnetic resonance data in k-space (e.g., undersampled data) as input data and output magnetic resonance images in image space (e.g., the spatial domain). Examples of such functions are those that use unrolled neural network architectures. An overview of deep-learning approaches in magnetic resonance reconstruction may, for example, be found in an article by Florian Knoll, “Deep-Learning Methods for Parallel Magnetic Resonance Imaging Reconstruction: A Survey of the Current Approaches, Trends, and Issues,” IEEE Signal Process Mag. 37 (2020 ), pages 128 to 140.

Such trained reconstruction algorithms allow a significant reduction of acquisition time with high acceleration factors, but with better image quality compared to conventional reconstruction methods such as generalized autocalibrating partially parallel acquisitions (GRAPPA) (see the article with the same name by Mark A. Griswald in Magn. Reson. Med. 47 (2002 ), pages 1202-1210). However, the noise-suppressing action of the trained function (e.g., the neural network involved) provides that image artifacts caused by motion are also reconstructed more visibly than with conventional reconstruction methods in which such artifacts are often lost in the noise. In principle, however, these reconstruction approaches, such as, for example, GRAPPA, are also affected by motion effects.

Various approaches for reducing motion artifacts have already been proposed in the prior art. A well-known example is scout accelerated motion estimation and reduction (SAMER) (see D. Polak et al., MRM 87 (2022), pages 163-178). In this approach, a reference dataset is acquired in a short reference scan at the start of the acquisition process. Then, several low-resolution navigator echoes are acquired in each sequence segment (e.g., echo train). Subsequently, in an optimization method in the image reconstruction process, the navigator echoes are fitted to the reference dataset in order to derive therefrom motion correction parameters that are used for suitable correction of the magnetic resonance data of the respective readout submodules. Currently, this approach cannot be combined with deep-learning reconstructions (e.g., the use of trained reconstruction functions) and therefore has only limited acceleration potential. In addition, it cannot be used to compensate for pulsating motion effects (e.g., pulsation effects).

It is proposed in the subsequently published German application DE 10 2024 203 342.1 that a method such as that mentioned in the introduction uses at least one navigator submodule in each readout module to acquire navigator data of the sequence segment along a k-space trajectory that runs through the center of k-space along the readout direction. For each sequence segment, the navigator dataset of the sequence segment is compared with at least one navigator dataset of a further sequence segment and the same k-space trajectory to ascertain correlation information that is then evaluated in order to select sequence segments, the magnetic resonance data of which is discarded, and/or to assign a weighting to the magnetic resonance data of at least some of the sequence segments prior to reconstruction of a magnetic resonance image. Therefore, the k=0 line is acquired in each sequence segment (e.g., in a Cartesian acquisition scheme). Since the trained reconstruction algorithm (e.g., an unrolled neural network) may obtain a mask of the acquired k-space lines, individual echo trains or sequence segments may be easily omitted if they are affected by strong motion.

However, it has been shown that, for example, motion along the phase-encoding direction leads to strong artifacts. However, since the navigator dataset acquired along the readout direction represents a projection onto the readout direction, motion substantially along the phase-encoding direction is insufficiently acquired with this method or, in extreme cases, not acquired at all.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method for obtaining magnetic resonance data that is improved in terms of motion artifacts through improved detection of pulsating motion and other types of motion is provided.

In a method of the type mentioned in the introduction, it is provided according to the present embodiments that: in each readout module, at least one navigator submodule is used to acquire navigator data of the sequence segment along a k-space trajectory, wherein, for at least one pair of navigator submodules, the k-space trajectory used therein runs at least partially along at least one phase-encoding direction of the acquisition process; for each sequence segment, correlation information is ascertained by comparing the navigator dataset of the sequence segment with at least one navigator dataset of a further sequence segment and the same k-space trajectory; and the correlation information is evaluated in order to select sequence segments, the magnetic resonance data of which is discarded, and/or to assign a weighting to the magnetic resonance data of at least some of the sequence segments prior to reconstruction of a magnetic resonance image.

Two fundamental approaches are conceivable here. While one option is to weight the magnetic resonance data of the sequence segments as a whole, for example depending on the magnitude of the motion described by the deviation in the comparison, another advantageous variant provides that, if at least one deviation condition evaluating the correlation information is satisfied for one of the sequence segments, the magnetic resonance data of at least the sequence segment is discarded or, in a subsequent reconstruction of a magnetic resonance image is given less weight than the magnetic resonance data of sequence segments of the same k-space trajectory that do not satisfy the deviation condition. In some example embodiments in which the k-space trajectory is changed with each new sequence segment (as will be explained later), the discarding and/or weighting may also relate to adjacent and/or intermediate sequence segments in which the same or a different k-space trajectory was used. If, for example, in the case of five slices, the k-space trajectory in the phase-encoding direction is used in the first, third and the fifth slices, the k-space trajectory in the readout direction is used in the second and fourth slices and the deviation condition is satisfied for the third and fifth slices but not otherwise, the slices acquired between the slices with motion, i.e., in this example the fourth slice, can also be discarded and/or weighted, possibly with interpolated strength. A weaker weighting or even discarding can also be applied for adjacent slices of a different k-space trajectory, here the second slice, wherein, however, since it is not exactly known when the motion starts or ends, the measure may be weakened overall. Obviously, if the deviation condition for the different k-space trajectory is satisfied intermediately or adjacently, a combination of weightings can be used. These explanations can also be applied, with appropriate restrictions, if the first and second space trajectories are changed after each repetition.

Partial correction in combination with discarding and/or weighting scenarios is also conceivable; this will be discussed in more detail below.

Due to the difference between the navigation dataset of an examined sequence segment and at least one navigator dataset of another sequence segment, the deviation condition or, in general, the presence of a deviation described by the correlation information with the same acquisition trajectory shows that the examined sequence segment may be affected by motion. Herein, motion in relation to a patient as the examination object can include both periodic body motion such as respiration and heartbeat, but also other voluntary or involuntary motion, in particular also macroscopic motion. In particular in relation to heartbeat, this is often referred to as pulsation. Therefore, the proposed method relates to improving the image quality of magnetic resonance images with respect to any motion in the acquisition region by identifying and discarding magnetic resonance data affected by motion or at least giving it less weight in the reconstruction in order to avoid motion artifacts.

Herein, discarding should be understood as meaning that the magnetic resonance data of the sequence segment is no longer included in a subsequent reconstruction. This means that at least one magnetic resonance image is reconstructed from the remaining magnetic resonance data from the acquisition process, so that the number of motion-induced artifacts can be significantly reduced due to the removal of motion-affected magnetic resonance data. This can also be achieved with lower weighting of such magnetic resonance data, wherein while it is possible to maintain a certain sampling density, the motion-affected magnetic resonance data has less effect on the magnetic resonance image. For example, this can specifically counteract the amplification effect with trained reconstruction functions that was mentioned in the introduction. Herein, one advantage of the procedure described here when used after the acquisition process is that it is easy to implement before the reconstruction, because only a simple step for identifying motion-affected sequence segments and discarding or specifying the weighting has to be inserted before the actual image reconstruction, but the reconstruction itself does not have to be modified.

For the reconstruction, it can be particularly advantageous to use a in particular trained reconstruction function that compensates for missing magnetic resonance data, in particular a reconstruction function based on an unrolled neural network architecture, which receives as input data magnetic resonance data in k-space and delivers as output data at least one magnetic resonance image in image space (spatial domain).

It is particularly advantageous to combine the identification and the discarding of motion-affected magnetic resonance data with trained reconstruction functions, in particular k-space-to-image-space-based unrolled neural networks (known, for example, as “deep resolve boost”) since these trained reconstruction functions are resilient to slight changes in the sampling pattern. This means that high-quality reconstruction is still possible despite potentially missing magnetic resonance data as a result of the discarding. In other words, the network architecture of the trained reconstruction function does not necessarily require regularly sampled magnetic resonance data as input data. Therefore, the method described here enables motion-affected sequence segments, in particular echo trains, to be detected and discarded prior to reconstruction.

However, in an advantageous development, it is also possible to introduce weighting into the input data of the reconstruction function. For example, it may be preferable, in addition to the magnetic resonance data as input data, for the trained reconstruction function also to use a sampling mask that describes the distribution of the sampled sample points in the sampled k-space, wherein-for magnetic resonance data to be discarded, the corresponding sample points are marked as not sampled and/or—for magnetic resonance data to be weighted, the weighting is entered into the sampling mask at the corresponding sample points, wherein the reconstruction function is embodied to use the weighting in the reconstruction and/or in a check of the consistency between the reconstruction result and the magnetic resonance data.

Herein, it can in particular be assumed that there is a binary sampling mask in which sampled points in k-space are assigned a ‘one’ and unsampled points are assigned a ‘zero’. In the case of discarded magnetic resonance data, the corresponding portions of k-space in the mask would simply be marked with zero. However, in the case of weighting, it is particularly advantageous to introduce values between zero and one. This can obviously also be transferred to sampling masks that work with other base values and/or even already use weighting. Therefore, the sampling mask determines how much weight the magnetic resonance data should be given in the reconstruction or in the data consistency check.

Herein, it can be particularly expedient to use weighting only or primarily for consistency checks. In this case, the magnetic resonance data contributes fully to the reconstruction, i.e., it retains the sampling base, but is given less consideration in the consistency check, so that motion-based artifacts can still be significantly reduced.

Obviously, combination with other reconstruction techniques, such as, for example, GRAPPA, is also conceivable in principle. Here, discarded magnetic resonance data in k-space, for example missing k-space lines, must be additionally reconstructed; in some circumstances, this may require the calculation of reconstruction kernels, for example GRAPPA kernels. It is also conceivable to implement a weighting mechanism.

In general, it can be said that weighting, in particular of magnetic resonance data to be weighted less, is selected depending on the magnitude of the deviation of the navigator data of one sequence segment from that of the at least one other sequence segment, in particular the magnitude of the infringement of the deviation condition (possibly with respect to a specific direction), and/or depending on their position in the sampled k-space. Herein, in some example embodiments, the magnitude of the deviation can be described directly by the correlation information, for example a correlation value. In particular with regard to the first-mentioned aspect of the position in k-space, it should be noted that it is also generally conceivable to select different weightings within a sequence segment, for example to select a higher weighting for magnetic resonance data relating to sample points located closer to the center of k-space than for magnetic resonance data located farther away from the center of k-space. For example, the weighting can be performed on the basis of k-space lines (or k-space trajectory segments). It can therefore be stated that, advantageously, central regions of sampled k-space should contribute more than the edge of sampled k-space because the majority of the signal is present in the central regions.

Additionally or alternatively, the weighting can depend on the magnitude of the deviation, in particular the infringement of the deviation condition that describes the magnitude of the relative detected motion. In the above-discussed example of the sampling mask that uses values from zero to one, the weighting can be close to zero for strong motion and close to one for only slight motion. For example, for sequence segments that satisfy the deviation condition, weighting can be selected that decreases linearly or otherwise with the magnitude of the infringement of the deviation condition. When changing the k-space trajectory between sequence segments and extending the weighting to adjacent and/or intermediate sequence segments of a different k-space trajectory, the weighting can be interpolated or extrapolated, for example linearly, wherein for example, for sequence segments that do not satisfy the deviation condition for which interpolation or extrapolation is to be performed, the correlation information or a weighting of one can still be taken into account. If the correlation information allows a corresponding breakdown, the deviation condition and/or the weighting can also be evaluated or selected with reference to at least one breakdown direction. For example, in scenarios in which motion in the phase-encoding direction can result in stronger artifacts, this motion can be weighted more heavily or, if at least at partial correction is possible in one breakdown direction, weighting can be based on the remaining breakdown direction(s).

However, it is also conceivable that, if no deviation condition is to be used, a magnitude of the deviation is ascertained for each sequence segment to determine the weighting, wherein the weighting decreases, in particular linearly, with the magnitude of the deviation. In other words, all sequence segments can be sorted depending on the magnitude of the deviation, i.e., in particular the strength of motion, and a weighting that decreases, in particular linearly, according to the strength of motion can be assigned to all sequence segments. The explanations relating to adjacent and intermediate sequence segments with k-space trajectory changes apply accordingly. Here, once again, the assignment can optionally be made with reference to a breakdown direction, in particular the or a phase-encoding direction.

A further general advantage of the method according to the present embodiments is that even short-term effects on the timescale of a single sequence segment, for example an echo train, can be identified and taken into account for a single slice. In particular, therefore, it is not necessary to discard or give less weight to a complete repetition, i.e., a TR period, if a motion effect only extends over a few hundred milliseconds of a sequence segment.

Herein, the method can be particularly advantageously used for turbo spin echo sequences (TSE sequences). It can thus be provided that the magnetic resonance sequence is a turbo spin echo sequence, wherein the radiofrequency pulses of the readout submodules are refocusing pulses. In TSE sequences, a radiofrequency excitation pulse is output in the preparation module and used in the echo train in respective TSE submodules for a plurality of readout periods. For this purpose, a radiofrequency refocusing pulse is output before each readout period.

Specifically, it is proposed that motion-affected sequence segments be identified based on an additional navigator echo for each sequence segment. Consequently, navigator data is acquired in at least one corresponding navigator submodule so that at least one navigator dataset is available for each navigator submodule, and hence for each sequence segment. Each navigator dataset is acquired using a specific k-space trajectory. This can be correlated, i.e. compared, with other navigator datasets that have used the same k-space trajectory in order to determine whether there is a motion-induced deviation. For example, the deviation condition can check whether there is a significant deviation that warrants special treatment.

In order to allow good comparability of the navigator datasets, in a development of the present embodiments, the navigator data for all sequence segments is acquired along at least one identical k-space trajectory in each case and/or the at least one k-space trajectory includes the center of k-space. Acquiring a k-space trajectory, in particular a k-space line, in the center of k-space has the advantage that the majority of the signal is present there, meaning that there is less noise and hence the comparison is further improved. Obviously, it is expedient to use the same radiofrequency pulse in all navigator submodules of the same k-space trajectory in order to improve comparability.

While, in the present case, the procedure can generally be used without changing the sequence segment timing, in particular the echo train timing, motion along the at least one phase-encoding direction can now be easily detected.

Herein, it should be noted that, for the sake of simplicity, most of the example embodiments discussed below refer to slice-by-slice acquisition and the phase-encoding direction used there. This typically uses a readout direction, a phase-encoding direction and a slice-selection direction. Three-dimensional sampling often works with two phase-encoding directions, which can obviously ideally be covered by at least some of the navigator submodules. Expediently, each navigator submodule in which the k-space trajectory running at least partially along the phase-encoding direction is used on the basis of a corresponding k-space trajectory gradient pulse, a prephrasing pulse assigned to the k-space trajectory gradient pulse and/or a rephasing pulse assigned to the k-space trajectory gradient pulse is output in the navigator submodule. On the one hand, the additional prephrasing pulse can be output before a radiofrequency pulse of the navigator submodule and, on the other hand (in particular with a differed prefix sign), can be output immediately before the k-space trajectory gradient pulse. The rephasing pulse is output after the navigator data readout process. This ensures that the gradient moment of the k-space trajectory gradient pulse is balanced. This is necessary to ensure that the CPMG conditions for the remaining echo/readout submodules remain satisfied.

In some example embodiments, the navigator dataset is in particular acquired at least partially perpendicular to the k-space lines of the magnetic resonance data in the readout direction. However, contrary to the problems described above, when using k-space trajectories that run (purely) in the phase-encoding direction, motion along the readout direction is no longer easy to detect. Even for “mixed directions” (e.g., k-space trajectories at a 45° angle to the readout direction and phase-encoding direction), a direction perpendicular thereto always results and this is more difficult to acquire. Example embodiments therefore provide for the use of at least two different k-space trajectories, for example a k-space line in the phase-encoding direction and a k-space line in the readout direction, preferably through the center of k-space in each case. Herein, various approaches are conceivable.

In general, it can therefore be said that it is preferable to use a first k-space trajectory, in particular running in the phase-encoding direction, and a second k-space trajectory, in particular running in a readout direction of the acquisition process, which are at an angle to one another in the plane formed by the phase-encoding direction and the readout direction, in particular perpendicular to one another. In particular, these are k-space lines running through the center of k-space. In the case of three dimensions, the concept described here can be extended analogously to a third k-space trajectory in the second phase-encoding direction or slab direction.

Preferably, the first and the second k-space trajectories are alternated across the navigation submodules according to a regular usage pattern. This ensures that both directions are regularly sampled for motion.

For example, each readout module may include (exactly) one navigator submodule and the first and second k-space trajectories can be changed with each new sequence segment. In a second variant of this example embodiment, it is also conceivable that the first and second k-space trajectories are changed after each repetition. With regard to the weighting and discarding of adjacent or intermediate sequence segments or repetitions, reference is made to the explanations already given above.

Therefore, in a first variant, the navigator orientation is so to speak rotated between the echo trains. In multislice acquisition, rotation can, for example, take place between the sequence segments of the N slices to be acquired. The advantage is that the direction of the navigator, i.e., specifically the k-space trajectory, is changed after each period corresponding to the repetition time divided by the number of slices N to be recorded, and thus even fast motion can be acquired along both orientations, i.e., in particular the phase-encoding direction and the readout direction, since this duration can, for example, be in the range of approximately 50 to 150 ms. Alternatively, in the second variant, the navigator orientation can also change with each repetition, i.e., in each case after an echo train has been acquired or a sequence segment has been performed for each slice.

However, it can be particularly advantageous to provide that each readout module includes two navigator submodules, one of which uses the first k-space trajectory and one which uses the second k-space trajectory. In this particular embodiment, at least two navigator datasets with k-space trajectories rotated relative to one another are acquired within a sequence segment. This is particularly advantageous because it enables differentiation of the directions of motion with a very high time resolution. The navigator submodules can follow each other directly in the readout module, but can also be separated by readout submodules.

In some embodiments, the procedure according to the present embodiments may extend the acquisition time, for example due to additionally required prephrasing and/or rephasing pulses and/or due to the use of a plurality of navigator submodules with different k-space trajectories for each sequence segment. Therefore, in a development of the present embodiments, the at least one k-space trajectory of the navigator submodule is selected shorter than the acquisition trajectory of the readout submodules. This does not detract from the function of the navigator, since a lower spatial Resolution is sufficient for the navigator dataset. On the other hand, however, this can save time, thus eliminating any additional time requirement. Consequently, an extension of the acquisition period can be compensated for by reduced resolution of the navigators.

In some example embodiments, the navigator submodule can correspond to a readout submodule for the k-space trajectory to be sampled for the navigator data. For example, in the case of a TSE echo train, an additional TSE echo for the k-space trajectory can be acquired in the navigator submodule. However, it is also conceivable, in particular with regard to compensating an extension of the acquisition process, to use a different echo type or sequence type for the navigator submodule, for example to measure a gradient echo in the case of a TSE sequence. The latter case can also have advantages if the navigator submodule is suitably arranged the readout module; this will be discussed in more detail below.

Preferably, in a first specific embodiment, the navigator data can be acquired at a fixed position relative to the readout submodules, in particular before all the readout submodules or after all the readout submodules. In this way, all navigator datasets are acquired under comparable conditions, which in turn improves comparability and simplifies the ascertaining of correlation information and, if necessary, the formulation of the deviation condition and/or a correctability condition. For example, at the beginning of each readout module, an additional echo, i.e., the navigator data, can be acquired in the navigator submodule, in particular in the region of the center of k-space. However, the navigator submodule can also be acquired at other positions of the sequence segment, for example at its end.

In an expedient specific embodiment, in the case of a turbo spin echo sequence as a magnetic resonance sequence, either the navigator submodule is a gradient echo submodule after all readout submodules, wherein the radiofrequency pulse (in this case an excitation pulse) of the navigator submodule is output with a flip angle that is reduced relative to the radiofrequency pulses of the readout submodules and/or at a time interval relative to the preceding radiofrequency pulse (i.e., refocusing pulse) of the last readout submodule that is shorter than the time interval between the radiofrequency pulses of the readout submodules. Here, it is therefore in particular possible to benefit from the fact that a gradient echo is not bound to the time interval of the refocusing pulses specified in the TSE sequence. Hence, the additional echo can be incorporated with only a slight extension of the acquisition period. This is particularly advantageous if an extension, for example by at least two navigator submodules for each sequence segment, is to be at least partially compensated for. Alternatively, it is also conceivable that the navigator submodule is a turbo spin echo submodule in which the refocusing pulse has a smaller flip angle. In both cases, the SAR load can be reduced by reducing the flip angle.

In an alternative second specific embodiment, in order to implement the acquisition of the navigator datasets at least partially in a time-neutral manner, the navigator submodules of the same k-space trajectory covering all possible positions in the readout module have at least partially different positions within the readout module, wherein the navigator data is additionally also evaluated to ascertain phase evolution information via the readout module which is used for eddy current effect correction of the magnetic resonance data. In the prior art, it is known to provide an eddy-current correction sequence segment, in particular an eddy-current correction echo train, before the first sequence segment used to acquire magnetic resonance data, in particular an echo train in TSE imaging, wherein, at each temporal position in the sequence segment, an echo only of the center of k-space is acquired, wherein the phase evolution between the different echoes is ascertained for the correction of eddy current effects. The correction ascertained is then applied in the subsequent sequence segments for the acquisition of magnetic resonance data. This second embodiment now proposes that the eddy-current correction sequence segment is omitted and instead navigator data of the center of k-space for at least one of the at least one k-space trajectory is acquired in each sequence segment at a different temporal position. The navigator data can then be used both as before for correcting eddy currents between the respective temporal positions and for identifying motion-affected sequence segments.

In this second embodiment, if magnetic resonance data of an echo train is discarded, it is also expedient not to use the navigator data for eddy-current correction. It can then be provided that, for sequence segments having correlation information that fulfils the deviation condition, the phase evolution information is interpolated and/or extrapolated while omitting navigator data of these sequence segments. Hence, the effect of motion is also avoided with regard to eddy current effects.

The correlation information can be ascertained, at least in part, as autocorrelation, in particular in image space. However, other correlation values, in particular correlation metrics, can be used as correlation information and other comparison methods can also be used. To ascertain the correlation, the navigator data of the same k-space trajectories can expediently be transposed into the image space by a Fourier transform. Sequence segments that deviate significantly can then be marked for discarding or suitable weighting can be selected.

In principle, it is conceivable to use a single sequence segment as a reference sequence segment and to check the degree of correlation of an examined sequence segment with the reference sequence segment. For example, the deviation condition can then check whether a correlation value describing the magnitude of the correlation or deviation, for example as a correlation metric, relating to the navigator data of the reference sequence segment included in the correlation information falls below a threshold value. However, it is preferable in each case to analyze the correlations between pairs of all sequence segments (which may have been traversed so far or covered by the same k-space trajectories) with one another in order to avoid discarding an entire acquisition because the reference sequence segment was affected by motion.

In a development of the present embodiments, the correlation information comprises at least one correlation value, in particular an average correlation value for the sequence segment, wherein a reference value is ascertained as the mean value of the correlation values across all sequence segments and the deviation condition checks whether the correlation value of the sequence segment falls below a threshold value dependent on the reference value, in particular 50 to 90% of the reference value.

In other words, it may be possible to check whether the at least one correlation value deviates from the reference value (mean value) by a threshold, in particular a percentage threshold. Herein, it should be noted that here, once again, it is possible to work with only one reference sequence segment to which the correlation value then refers. However, it is preferable to refer to all sequence segments (possibly acquired so far or covered by the same k-space trajectories), so that the correlation information may include an average correlation value for pairs with respect to all these sequence segments. In this way, the sequence segments that represent outliers are easily filtered out by the deviation condition, while the (usually) greater body of similar navigator data indicates sequence segments that are little affected by motion and can be retained, in particular with maximum weighting, for the reconstruction of a magnetic resonance image.

In particular when k-space trajectories for different directions, for example the phase-encoding direction and the readout direction, are used as k-space lines, the correlation information can be ascertained at least partially broken down according to the readout direction and the phase-encoding direction as breakdown directions. In other words, comparisons of navigator datasets acquired along a first k-space trajectory in the readout direction indicate motion components along the readout direction, while comparisons of navigator datasets acquired along a second k-space trajectory in the phase-encoding direction indicate motion components along the readout direction. The scope of the present embodiments includes embodiments in which a breakdown of the correlation information in this manner is useful. For example, it is conceivable to weight deviations in one breakdown direction differently than in the other breakdown direction. If, for example, it is known that motion in the phase-encoding direction leads to more disruptive artifacts than in the readout direction, threshold values for discarding the magnetic resonance data can be selected differently or weightings can be scaled differently with the magnitude of the deviation. In other words, it is also possible to select different deviation conditions for different breakdown directions where appropriate.

It is also conceivable in principle to combine the approach of discarding and/or weighting with a partial correction approach. For example, it can be provided that, if a correctability condition which evaluates the correlation information for a first of the breakdown directions is satisfied for one of the sequence segments and, at least in the case of a greater deviation in the first breakdown direction, in particular the readout direction, than in the other breakdown direction, in particular the phase-encoding direction, the magnetic resonance data of this sequence segment in the first breakdown direction is corrected depending on the correlation information for the first breakdown direction, in particular by a shift in image space and/or a phase ramp in k-space. For example, if the magnetic resonance data is processed to allow correction of motion in the readout direction in a simple manner, the portion of the correlation information relating to this direction can be used to correct the magnetic resonance data of a corresponding sequence segment, while the portion of the correlation information relating to the phase-encoding direction can be evaluated with regard to discarding or weighting. If, despite a deviation, the correctability condition is not satisfied, for example because the deviation is too large, obviously discarding/lower weighting with respect to the readout direction can also take place. In certain cases, the incorporation of corrections can further improve image quality.

In an advantageous embodiment, it is, for example, possible first to evaluate whether motion along the phase-encoding direction or along the readout direction predominates. Sequence segments with strong motion along the phase-encoding direction continue to be discarded or given low weighting. Remaining sequence segments in which rigid motion along the readout direction has been detected (specifically, for example, a translation of the course of the navigator data along the readout direction) can, for example, be corrected by a geometric shift in image space or a phase ramp in k-space in order to enhance image quality.

In a development of the present embodiments, a maximum number of magnetic resonance datasets of individual sequence segments to be discarded is used which, if exceeded, either invalidates the entire acquisition process or adapts the deviation condition, in particular a threshold value, in order to comply with the maximum number, and/or sequence segments, the magnetic resonance data of which is to be reintroduced for reconstruction despite fulfilling the deviation condition, are selected by means of at least one selection criterion in order to comply with the maximum number. The maximum number can depend on the specific acquisition process, for example the acceleration measures, and the possibilities for compensating for missing magnetic resonance data in the reconstruction of magnetic resonance images, in particular when a trained reconstruction function is used. For example, the maximum number can be selected depending on an acceleration factor and/or a number of sequence segments. If this is exceeded, i.e., if more sequence segments than the maximum number satisfy the deviation condition, the magnetic resonance data from the acquisition process as a whole can be discarded and in particular re-acquisition can be recommended. However, it is also possible, in particular after confirmation by a user, to still attempt reconstruction. The deviation condition can then be adapted, for example by raising or lowering a threshold value, or at least one selection criterion is used to select magnetic resonance data that has actually been discarded but is nevertheless to be reintroduced. At least one of the at least one selection criterion can relate to the magnitude of the infringement of the deviation condition. However, it is particularly advantageous if at least one of the at least one selection criterion relates to the coverage of the k-space to be sampled, in particular the distribution of the k-space points at which measurements were made. In a specific example, the resulting maximum interval between k-space lines of the sequence segment, in particular in the echo train, can serve as a selection criterion, i.e., in the case of echo trains with similar deviations according to the correlation information, where discarding one echo train causes a maximum undersampling of four, while discarding the other echo train causes an undersampling of six, the choice is to retain or re-introduce the echo train with undersampling of four.

In this context, it should also be noted that it is expediently also possible to synergistically combine other fundamentally known techniques for avoiding excessive (local) undersampling with the procedure according to the present embodiments. One example of this is the procedure known as “Reduce Motion Sensitivity”. For this purpose, it may be provided that there is no fixed assignment of k-space lines (or different k-space trajectory segments) to temporal positions of readout submodules in the readout module, but rather that the k-space lines or k-space trajectory segments to be acquired are allocated to the readout submodules randomly or pseudo-randomly within the readout module. This enables the probability of large k-space gaps in regular undersampling to be minimized.

In an advantageous group of example embodiments, the correlation information can be ascertained and the deviation condition can be checked at least partially during the acquisition process, in particular immediately after the acquisition of the navigator data and/or completion of the sequence segment, wherein the magnetic resonance data to be discarded from a sequence segment for which deviation condition is satisfied, can be at least partially re-acquired in a subsequent sequence segment adapted for this purpose. Additionally or alternatively to an assessment after the acquisition process, in particular before reconstruction, to determine weights and/or magnetic resonance data to be discarded, it can therefore also be provided that an identification of sequence segments to be discarded is performed dynamically during the acquisition process. This makes it possible to modify the acquisition process in order to compensate for the omission and/or lessen the consequences. In particular, it can thus be provided that the sequence segment is repeated, in particular immediately or at the end of the planned sequence segment. The acquisition protocol can also be planned with a view to checking for motion during acquisition.

In this context, in an expedient development, for a fixed or maximum specified number of sequence segments, their sequence within the acquisition protocol is defined in such a way that, with each sequence segment, the interval between sampled k-space trajectory segments, in particular k-space lines, is minimized in k-space. If, for example, the current sequence segment, in particular the current echo train, is then identified as to be discarded by means of the deviation condition, the subsequent sequence segment is adapted such that it re-samples the k-space-positions of the previously discarded sequence segment. Even if sequence segments would ultimately have to be omitted, this ensures that sampling of k-space is performed with minimum possible intervals, thereby enabling more robust and higher-quality compensation for or estimation of missing magnetic resonance data in the reconstruction.

Expediently, in this context, the maximum number of possible sequence segments can be selected as greater than the number of sequence segments required for motion-free sampling. For example, when the functionality described here is activated, time can be reserved for reserve sequence segments in order to allow repetitions within a certain range without omitting sequence segments. Furthermore, it is conceivable to slightly lessen the planned undersampling in order to avoid negative effects caused by overlarge sampling gaps.

Overall and in general, it can therefore be said that, by identifying and discarding or giving lower weight to defective sequence segments, in particular in combination with deep-learning reconstruction methods, increased image quality and greater insensitivity to motion is achieved, in particular also in the phase-encoding direction. Compared to motion correction approaches such as SAMER, the present embodiments have the advantage that it can be combined with the use of trained reconstruction functions and pulsation effects can also be taken into account.

In addition to the method, the present embodiments also relate to a magnetic resonance facility having a main magnet unit with a main magnet for generating a main magnetic field, a gradient coil arrangement, a radiofrequency coil arrangement and a control facility having: a sequence unit for controlling an acquisition process in an acquisition process in accordance with an acquisition protocol, which includes, in at least one repetition, a plurality of sequence segments of a magnetic resonance sequence, wherein each sequence segment includes a preparation module and a readout module, and each readout module includes a plurality of readout submodules in which in each case radiofrequency pulses precede readout periods for acquiring magnetic resonance data, wherein the sequence unit is configured, in each readout module, to use at least one navigator submodule for acquiring navigator data of the sequence segment along a k-space trajectory, wherein, for at least one pair of navigator submodules the k-space trajectory used therein runs at least partially along at least one phase-encoding direction of the acquisition process; a correlation unit for ascertaining correlation information for each sequence segment by comparing the navigator dataset of the sequence segment with at least one navigator dataset of a further sequence segment and the same k-space trajectory, and an evaluation unit for evaluating the correlation information in order to select sequence segments, the magnetic resonance data of which is to be discarded, and/or assigning a weighting to the magnetic resonance data of at least some of the sequence segments.

In particular, the evaluation unit can, for example, be embodied to discard and/or assign a lower weighting to magnetic resonance data of at least one sequence segment for which at least one deviation condition evaluating the correlation information is satisfied.

All statements relating to the method according to the present embodiments may be transferred analogously to the magnetic resonance facility according to the present embodiments and vice versa, so that the same advantages may be obtained.

The control facility may include at least one processor and at least one storage means. Hardware and/or software forms functional units for performing steps of the method according to the present embodiments, in the present case at least a sequence unit, a correlation unit and an evaluation unit, wherein a reconstruction unit is also known in principle for control facilities of magnetic resonance facilities known and accordingly also usefully provided according to the present embodiments. Further functional units can obviously likewise be provided, in particular with regard to the various proposed embodiments. For example, an adaptation unit may be provided for adapting the acquisition protocol during assessment during the acquisition process. Herein, the sequence unit corresponds in principle to known sequence units for control facilities of magnetic resonance facilities that control the acquisition operation.

A computer program according to the present embodiments may be loaded directly into a storage means of control facility of a magnetic resonance facility and has program means such that, when the computer program is executed in the control facility, the control facility is caused to perform the steps of a method according to the present embodiments. The computer program may be stored on an electronically readable data carrier according to the present embodiments that therefore has control information stored thereon that includes at least one computer program according to the present embodiments and is configured such that, when the data carrier is used in a control facility of a magnetic resonance facility, the latter is embodied to perform a method according to the present embodiments. The data carrier is in particular a non-transitory data carrier, for example a CD-ROM.

### BRIEF DESCRIPTION OF THE DRAWINGS

FIG. 1 is a flowchart of a first example embodiment of a method;

FIG. 2 is an example extract from a sequence diagram of a TSE sequence in a first variant;

FIG. 3 is an example extract from a sequence diagram of a TSE sequence in a second variant;

FIG. 4 is a flowchart of a second example embodiment of the method;

FIG. 5 is a schematic view of a sampling diagram in the second example embodiment;

FIG. 6 is a schematic diagram of a magnetic resonance facility according to an embodiment; and

FIG. 7 is the functional structure of the magnetic resonance facility in FIG. 6.

### DETAILED DESCRIPTION

The following is a specific example of the application of the method according to the present embodiments for an acquisition process with an acquisition protocol that uses a TSE sequence. A plurality of slices that follow one another in a slice-selection direction are acquired in a plurality of repetitions, wherein, in each repetition, echo trains of a specific length from readout modules, here TSE submodules are initially used as sequence segments in order to acquire magnetic resonance data, in the present case, a k-space line in each readout period following a radiofrequency refocusing pulse. Herein, the k-space lines of the readout submodules run in a readout direction that is perpendicular to a phase-encoding direction. This example and also the use of a TSE sequence should be understood as being purely by way of example.

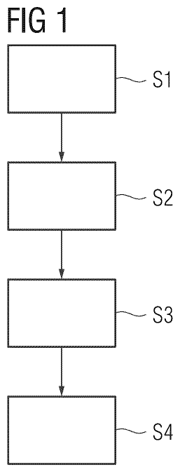

FIG. 1 shows a flowchart of a first example embodiment of the method according to the present embodiments. Here, magnetic resonance data is initially acquired in step S1 in the respective sequence segments, i.e., echo trains, wherein, in addition to the readout submodules, at least one navigator submodule is also used in each sequence segment to acquire navigator data. In the present example embodiments, the navigator submodule always samples one of two predefined k-space trajectories through the center of k-space. The first of the two k-space trajectories is a k-space line in the phase-encoding direction, the second of the two k-space trajectories is a k-space line in the readout direction. The remaining readout submodules use different encodings in the sequence segments, i.e., different k-space trajectory segments.

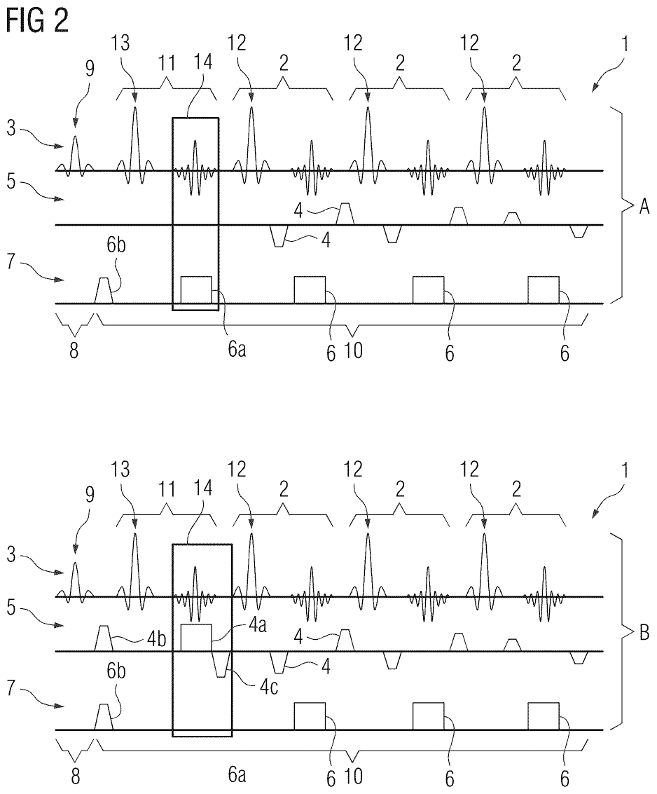

FIG. 2 shows a variant of a first embodiment. For purposes of simplicity, only two successive sequence segments 1 are illustrated, of which only three readout submodules 2 are shown; in practical use, this number will be higher. In addition, this figure only indicates the radio-frequency activity in a top graph 3, the phase-encoding gradient pulses 4 in a center graph 5 and the readout gradient pulses 6 in a bottom graph 7.

It can be seen that each sequence segment 1 includes a preparation module 8, in the present case symbolized by a radiofrequency excitation pulse 9, and a readout module 10, which is subdivided into the readout submodules 2 and also a navigator submodule 11. In the present case, each readout submodule 2 and the navigator submodule 11 include radiofrequency pulses 12, 13 preceding the readout gradient pulses 6, 6a defining the respective readout periods. The radiofrequency pulses 12 for the readout submodules 2 embodied as TSE submodules are used for refocusing. The navigator submodule 11 can likewise be embodied as a TSE submodule, wherein then the flip angle of the radio-frequency pulse 13, which is likewise used for refocusing, is selected as smaller. However, it is also conceivable to select the navigator submodule 11 according to another sequence type, for example as a gradient echo submodule in which the radiofrequency pulse 13 can be used to excite the gradient echo and can be closer to the radiofrequency pulse 12 of the preceding readout submodule 2 than the intervals between the radiofrequency pulses 12 per se.

It can be seen that two different types of navigator submodules 11 are alternated successive sequence segments 1. In the upper sequence segment 1, marked “A”, the absence of phase-encoding gradient pulses 4 for the navigator submodule 11 when using a readout gradient pulse 6a indicates the measurement of a k-space line in the readout direction through the center of k-space. Therefore, the second k-space trajectory is used.

In the lower sequence segment 1, marked “B”, no gradient pulses are used in the readout direction during the readout period; instead, a k-space line is read out in the phase-encoding direction by means of a phase-encoding gradient pulse 4a, which defines the readout period, i.e., the first k-space trajectory perpendicular to the second k-space trajectory. The phase-encoding gradient pulse 4a is flanked by a prephrasing pulse 4b and a rephasing pulse 4c. In the present case, the prephrasing pulse 4b is output before the radiofrequency pulse 13 of the navigator submodule 11, since a readout gradient pulse 6b occurs at that time anyway, thereby allowing temporal optimization.

In each case, the navigator echoes 14 are acquired as navigator data for both types of navigator submodule 11, so that a navigator dataset exists for each sequence segment 1.

In the embodiment in FIG. 2, the temporal position of the navigator submodule 11 in the readout module 10 is fixed at the start of the readout module 10. In principle, other fixed positions are also conceivable in the first embodiment, for example at the beginning of the readout module 10.

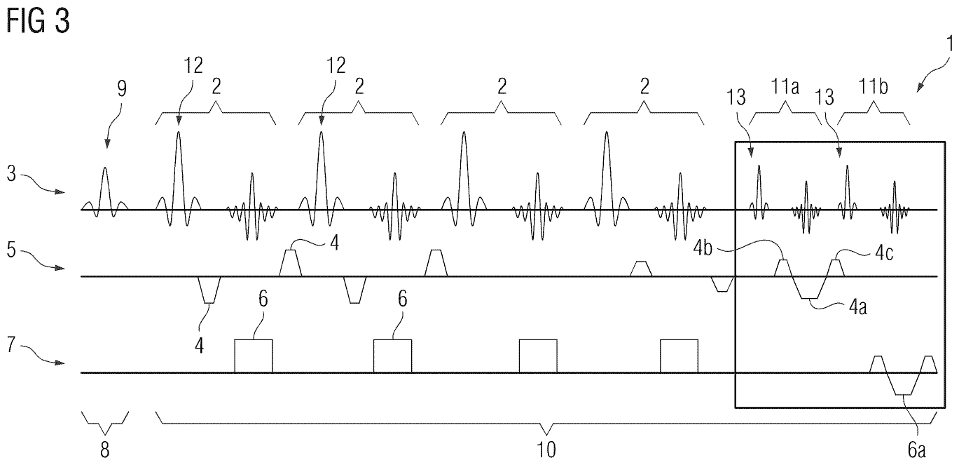

FIG. 3 is a schematic illustration of a second embodiment in which two navigator submodules 11a, 11b are used at the end of the respective readout module 10. It can be seen that the first navigator submodule 11a, recognizable by the phase-encoding gradient pulses 4a, 4b and 4c, uses the first k-space trajectory, i.e., the k-space line in the phase-encoding direction, to acquire a first navigator dataset assigned to this k-space trajectory. The second navigator submodule uses the second k-space trajectory, see readout gradient pulse 6a, i.e., the k-space line in the readout direction. A second navigator dataset assigned to this k-space trajectory is acquired. Since two navigator echoes are acquired, the duration of the sequence segment 1 would in principle be extended. In order to compensate for this at least in part, reduced resolution of the navigators is provided (by reducing the length of the first and second k-space trajectories compared to the k-space line sections of the readout submodules 2). In addition, gradient echoes with a reduced flip angle are interwoven, thereby further shortening the duration of the navigators. It should be noted that these time-saving measures can obviously also be advantageously used in other embodiments.

Embodiments are also conceivable in which the temporal position of the at least one navigator submodule 11, 11a, 11b is not fixed but varies such that all possible temporal positions in the readout module 10 are traversed at least by the navigator submodules 11, 11a, 11b that use the first k-space trajectory in the readout direction, but preferably by both navigator submodules 11. The corresponding navigator datasets can then also be used for eddy-current correction, since the phase evolution for the various temporal positions can be tracked from the navigator data. This eliminates the need for a separate sequence segment for the eddy-current correction navigators. If, as will be explained later, only navigator data affected by motion is available for a temporal position in the readout module 10, it is possible to omit this data and interpolate or extrapolate the eddy-current correction, the phase evolution or the missing navigator data. However, in some cases, there may anyway be redundant acquisition of the navigator data for at least some of the temporal positions, namely whenever the number of sequence segments is greater than the echo train length.

Regardless of which specific embodiment was used, in step S2 in FIG. 1, after completion of the acquisition process, i.e., when navigator data is available for all sequence segments 1, correlation information is determined for each sequence segment 1. This is done by ascertaining the autocorrelation of the navigator data paired with respect to all other sequence segments 1 in which the same k-space trajectory was used for each sequence segment 1. In the second embodiment in FIG. 3, navigator datasets are available for the first and the second k-space trajectories for each sequence segment, which can then be compared in each case in order to ascertain motion in both directions precisely for each sequence segment. The navigator data items of the same acquisition trajectory are thus compared with one another. An average correlation value is determined by forming the statistical mean of the individual results. In this context, a reference value can also be ascertained as the mean value of all average correlation values. In the present case, the correlation value is ascertained in such a way that higher values indicate a higher correlation.

In step S3, the correlation information for each sequence segment 1 is evaluated by a deviation condition. In the present case, the deviation condition checks whether the average correlation value of the correlation information of the respective sequence segment 1 is less than a threshold value that is derived as a percentage from the reference value, for example as 50% to 90% of the reference value. It is conceivable to use different deviation conditions for different breakdown directions, here the readout direction and the phase-encoding direction, if motion in one of these directions can lead to stronger artifacts.

If the deviation condition is satisfied, i.e., if the navigator data differs significantly from the navigator data of most of the other sequence segments 1 with the same k-space trajectory, it is inferred that there was motion during sequence segment 1, which could also be pulsation. Since the magnetic resonance data that was acquired in the readout submodules 2 of sequence segment 1 may also be affected by the motion, this data is discarded and/or is assigned a lower weighting for subsequent reconstruction than magnetic resonance data for sequence segments 1 for which the deviation condition is not satisfied. The weightings are expediently selected depending on the position in k-space and the magnitude of the infringement of the deviation condition, i.e., the strength of the motion. The selection of the weighting can also depend on the breakdown direction. For example, the sequence segments 1 for which the deviation condition is satisfied, can be sorted depending on the magnitude of the infringement and assigned lower weightings as the magnitude of the infringement increases, possibly modified with the k-space position.

When using the first embodiment according to FIG. 2, discarding and/or weighting can also be applied to adjacent and/or intermediate sequence segments 1 in which a different k-space trajectory was used. If, for example, a sequence segment 1 lies between two sequence segments 1 in which strong motion was detected in the phase-encoding direction leading to their being discarded, it can be assumed that this motion is also present in the intermediate sequence segment 1, which can then likewise be discarded. If the two sequence segments 1 with motion are merely weighted, the weighting of the magnetic resonance data of the intermediate sequence segment can, for example, be selected interpolated between these weights. Weighting can also be applied to adjacent sequence segments 1 (toward those where the deviation condition is not satisfied), for example in a predefined attenuated form or ascertained again by interpolation/extrapolation, for example depending on the correlation information and/or relative to the weighting of one. These weightings of intermediate sequence segments 1 can be cumulative for both the phase-encoding direction and the readout direction. This means that, if weighting based on motion in the phase-encoding direction and weighting based on motion in the readout direction are ascertained for a sequence segment 1, both can be used, for example by multiplying the weights lying in an interval from zero to one.

The remaining or weighted magnetic resonance data is then used in step S4 to reconstruct at least one magnetic resonance image. For this purpose, a trained reconstruction function is used which ascertains a magnetic resonance image in image space, i.e., the spatial domain, as output data from the magnetic resonance data in k-space as input data. Preferably, the trained reconstruction function is based on an unrolled neural network architecture. Such deep-learning-based reconstruction functions can compensate particularly well and robustly for the omission of magnetic resonance data, so that, despite the omission of motion-affected magnetic resonance data according to step S3, high-quality magnetic resonance images are reconstructed that, due to the omission, are unaffected or less affected by motion artifacts.

If weighting is used, the trained reconstruction function can use a sampling mask of the sampled k-space as additional input data. Here, for lower-weighted magnetic resonance data at the corresponding sample points in k-space, weightings between zero and one are entered instead of one (sampled: full weighting) or zero (not sampled: do not use). Weighting can be applied in the reconstruction and/or a consistency check between the reconstruction result and the magnetic resonance data, particularly preferably at least in the latter case.

Herein, it should be noted at this point that a maximum number of sequence segments for which magnetic resonance data can be discarded can also be specified so that reliable reconstruction is still possible. This maximum number can depend both on properties of the trained reconstruction function and on properties of the acquisition protocol, for example the acceleration factor and the number of sequence segments 1. If the maximum number is exceeded in step S3, the entire acquisition process can be deemed invalid due to motion, and the user is notified accordingly. If reconstruction is still desired, various procedures are conceivable. For example, on the one hand, it is possible to adapt the deviation condition, in this example embodiment in particular the threshold value, so that the maximum number is not exceeded. However, it is also possible to use selection criteria to reintroduce magnetic resonance data from certain sequence segments 1, wherein, in addition to the magnitude of the infringement of the deviation condition, the selection criterion used can, for example, be an increase in the (possibly local) undersampling due to the omission of the magnetic resonance data.

In step S3, a deviation condition can also be dispensed with and all sequence segments 1, and hence magnetic resonance data, can be assigned a weighting based at least on the magnitude of the deviation (and hence the magnitude of the motion) in the comparison, in particular described by the average correlation value. For example, the sequence segments 1 can be sorted according to the magnitude of the motion and all sequence segments 1 can be weighted according to the magnitude of the motion, in particular in a linearly decreasing manner.

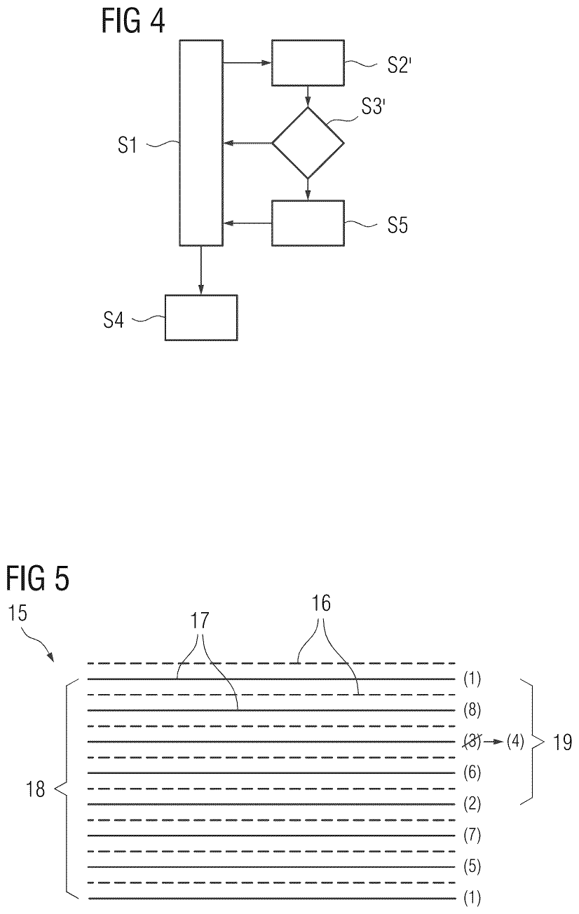

FIG. 4 shows a flowchart of a second example embodiment of the method according to the present embodiments. Once again, magnetic resonance data and navigator data are acquired according to the acquisition protocol in step S1. However, during the acquisition process, in step S2′, correlation information is ascertained with regard to the navigator datasets recorded so far and, in step S3′, it is checked whether the deviation condition is satisfied. If the deviation condition for a current sequence segment 1 is satisfied, in step S5, the acquisition protocol is adapted in order to at least partially re-acquire the discarded magnetic resonance data of sequence segment 1, in particular to repeat sequence segment 1. Here, it is conceivable to allow time for reserve sequence segments in the acquisition protocol so that, despite discarded magnetic resonance data in a few sequence segments 1, complete coverage of k-space can be achieved as planned. However, it is also expedient, in particular additionally, to plan the acquisition protocol in advance so as to enable the best possible coverage with small gaps in the k-space to be acquired. Here, the order of the sequence segments 1 can in particular be selected such that, with each sequence segment 1, the maximum interval between sampled locations in k-space is reduced to the maximum extent possible.

This will be explained in more detail with reference to FIG. 5, which is shows schematically an extract 15 from the k-space to be sampled. Herein, k-space lines 16 shown with dashed lines are not to be sampled anyway, but k-space lines 17 shown as solid lines are to be sampled. The numbers in parentheses to the right of the k-space lines 16, 17 indicate the sequence segment 1 for their sampling. It can be seen that, in the first sequence segment 1, marked (1), a large interval 18 is created in k-space and is reduced to the maximum extent possible by the acquisition in the second sequence segment 1, marked (2), see interval 19. This is also planned for the third sequence segment 1, marked (3), but this is discarded in step S3′ because the usability condition is satisfied (and is therefore crossed out). Consequently, in step S5, the acquisition protocol is adapted such that, in the fourth sequence segment 1, marked (4), the k-space lines 17 of the sequence segment 1 for which the magnetic resonance data was discarded are sampled again. This minimizes the gap between (1) and (2) as quickly as possible.

The applicable statements relating to the first example embodiment obviously also apply to the second example embodiment. It is also conceivable to combine the example embodiments, whereby, proceeding from the second example embodiment, correlation information is ascertained again for all sequence segments 1 after the acquisition process and evaluated for weighting, possibly by means of a different or modified deviation condition or independently of such a condition.

In conclusion, it should be noted that the functionality described here, i.e., the identification of motion-affected sequence segments 1 and the discarding or weighting of their magnetic resonance data using navigator data in conjunction with a trained reconstruction function, can be activated on the magnetic resonance facility used. Activating this functionality then also allows for the inclusion of the aforementioned reserve sequence segments. In addition, it can be expedient to slightly reduce the undersampling in order in this way to counteract negative effects resulting from overlarge sampling gaps due to discarded magnetic resonance data.

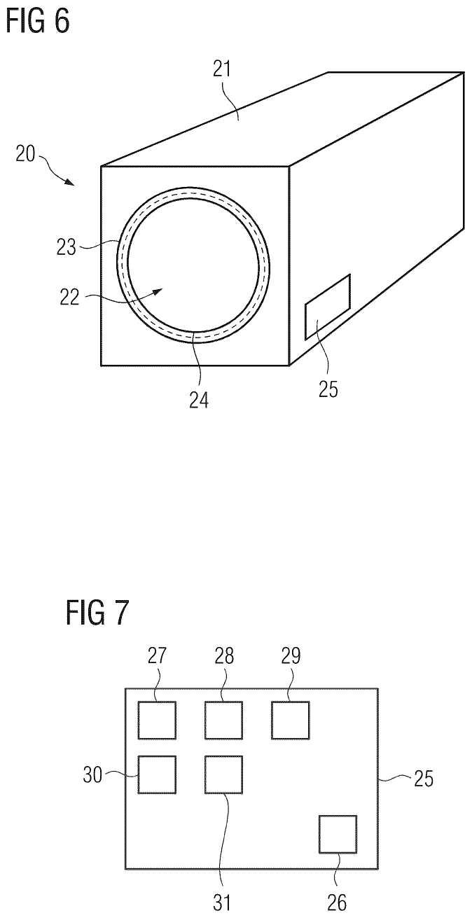

FIG. 6 is a schematic diagram of a magnetic resonance facility 20 according to the present embodiments. The magnetic resonance facility 20 includes a main magnet unit 21 which contains a superconducting main magnet (not shown in detail) and has a cylindrical patient bore 22 into which a patient can be moved for an acquisition process with a patient couch (not shown in detail). In the present case, the patient bore 22 is surrounded by a gradient coil arrangement 23 and a radiofrequency coil arrangement 24.

The operation of the magnetic resonance facility 20 is controlled by a control facility 25, the functional structure of which is described in more detail in FIG. 7. Accordingly, the control facility 25 initially includes a storage means 26 (e.g., storage device) in which various data, in particular also magnetic resonance data, navigator data, correlation information and the like, can be stored.

The control facility 25 further includes a sequence unit 27, which controls the acquisition operation of the magnetic resonance facility 20, in particular using an acquisition protocol according to step S1. Correlation information can be ascertained in a correlation unit 28 according to steps S2, S2′. In an evaluation unit 29, motion-affected sequence segments are then identified by evaluating the deviation condition according to steps S3, S3′ and their magnetic resonance data is discarded. In an adaptation unit 30, the acquisition protocol can be adapted according to step S5. A reconstruction unit 31 is used to reconstruct magnetic resonance images from the (if applicable remaining) magnetic resonance data according to step S4 using a trained reconstruction function, which is in particular based on an unrolled neural network architecture.

Independent of the grammatical term usage, individuals with male, female or other gender identities are included within the term.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for operating a magnetic resonance facility in an acquisition process in accordance with an acquisition protocol that includes, in at least one repetition, a plurality of sequence segments of a magnetic resonance sequence, wherein each sequence segment of the plurality of sequence segments comprises a preparation module and a readout module, and each readout module comprises a plurality of readout submodules in which in each case radiofrequency pulses precede readout periods for the acquisition of magnetic resonance data, the method being computer-implemented and comprising:
acquiring navigator data of the respective sequence segment along a k-space trajectory using, in each readout module, at least one navigator submodule, wherein, for at least one pair of navigator submodules, the k-space trajectory used therein runs at least partially along at least one phase-encoding direction of the acquisition process;
ascertaining, for each sequence segment of the plurality of sequence segments, correlation information, the ascertaining comprising comparing a navigator dataset of the respective sequence segment with at least one navigator dataset of a further sequence segment of the plurality of sequence segments and the same k-space trajectory; and
evaluating the correlation information in order to select sequence segments of the plurality of sequence segments, the magnetic resonance data of which is discarded, to assign a weighting to the magnetic resonance data of at least some sequence segments of the plurality of sequence segments, or a combination thereof prior to reconstruction of a magnetic resonance image.

2. The method of claim 1, wherein the navigator data for all sequence segments of the plurality of sequence segments is acquired along at least one in each case same k-space trajectory, each k-space trajectory contains the center of k-space, or a combination thereof.

3. The method of claim 1, wherein a first k-space trajectory and a second k-space trajectory are used and are at an angle to one another in a plane formed by the phase-encoding direction and the readout direction.

4. The method of claim 3, wherein the first k-space trajectory runs in the phase-encoding direction, and the second k-space trajectory runs in a readout direction of the acquisition process, and
wherein the first k-space trajectory and the second k-space trajectory are perpendicular to one another.

5. The method of claim 3, wherein the first k-space trajectory and the second k-space trajectory are alternated according to a regular usage pattern via the navigation submodules.

6. The method of claim 5, wherein each readout module comprises a navigator submodule, and the first k-space trajectory and the second k-space trajectory are changed with each new sequence segment, or
wherein the first k-space trajectory and the second k-space trajectory are changed after each repetition.

7. The method of claim 5, wherein each readout module comprises two navigator submodules, one of which uses the first k-space trajectory and the other of which uses the second k-space trajectory.

8. The method of claim 1, wherein the at least one k-space trajectory of the navigator submodule is selected to be shorter than an acquisition trajectory of the readout submodules.

9. The method of claim 1, wherein the navigator data is acquired at a fixed position relative to the readout submodules.

10. The method of claim 9, wherein the fixed position is before all readout submodules or after all readout submodules.

11. The method of claim 8, wherein, in the case of a turbo spin echo sequence as a magnetic resonance sequence in which the radiofrequency pulses of the readout submodules are refocusing pulses, the navigator submodule is a gradient echo submodule after all readout submodules, and
wherein an excitation pulse of the navigator submodule is output with a flip angle that is reduced relative to the radiofrequency pulses of the readout submodules, at a time interval relative to the preceding radiofrequency pulse of the last readout submodule that is shorter than the time interval between the radiofrequency pulses of the readout submodules, or a combination thereof, or the navigator submodule is a turbo spin echo submodule in which the refocusing pulse has a smaller flip angle.

12. The method of claim 1, wherein the navigator submodules cover all possible positions in the readout module and have at least partially different positions within the readout module, and
wherein the navigator data is additionally also evaluated to ascertain phase evolution information via the readout module, which is used to correct the magnetic resonance data for eddy-current effects.

13. The method of claim 1, wherein when at least one deviation condition evaluating the correlation information is satisfied for one of the sequence segments, the magnetic resonance data of at least the sequence segment is discarded or, in a subsequent reconstruction of a magnetic resonance image, is weighted less than the magnetic resonance data of sequence segments of the plurality of sequence segments that do not satisfy the deviation condition.

14. The method of claim 1, wherein the correlation information is ascertained at least partially broken down according to the readout direction and the phase-encoding direction as breakdown directions.

15. The method of claim 14, wherein when a correctability condition that evaluates the correlation information for a first of the breakdown directions is satisfied for one sequence segment of the plurality of sequence segments, at least in the case of a greater deviation in the first breakdown direction than in the other breakdown direction, the magnetic resonance data of the one sequence segment in the first breakdown direction is corrected depending on the correlation information for the readout direction.

16. The method of claim 15, wherein the first breakdown direction is the readout direction, and the other breakdown direction is the phase-encoding direction, and
wherein the magnetic resonance data of the one sequence segment in the first breakdown direction is corrected by a shift in image space, a phase ramp in k-space, or the shift in image space and the phase ramp in k-space.

17. The method of claim 1, wherein a trained reconstruction function that compensates for missing magnetic resonance data, and receives as input data magnetic resonance data in k-space and delivers as output data at least one magnetic resonance image in image space is used for the reconstruction.

18. The method of claim 17, wherein in addition to the magnetic resonance data as input data, the trained reconstruction function also uses a sampling mask that describes a distribution of the sampled sample points in the sampled k-space,
wherein for magnetic resonance data to be discarded, the corresponding sample points are marked as not sampled, for magnetic resonance data to be weighted differently, the weighting is entered into the sampling mask at the corresponding sample points, or a combination thereof, and
wherein the reconstruction function is configured to use the weighting in the reconstruction, to check the consistency between the reconstruction result and the magnetic resonance data, or a combination thereof.

19. A magnetic resonance facility comprising:
a main magnet unit comprising a main magnet for generating a main magnetic field;
a gradient coil arrangement;
a radiofrequency coil arrangement; and
a control facility comprising:
a sequence unit configured to control an acquisition process in accordance with an acquisition protocol that comprises, in at least one repetition, a plurality of sequence segments of a magnetic resonance sequence, wherein each sequence segment of the plurality of sequence segments comprises a preparation module and a readout module, and each readout module comprises a plurality of readout submodules in which in each case radiofrequency pulses precede readout periods for acquiring magnetic resonance data, wherein the sequence unit is configured, in each readout module, to use at least one navigator submodule for acquiring navigator data of the sequence segment along a k-space trajectory, wherein, for at least one pair of navigator submodules (11, 11a, 11b), the k-space trajectory used therein runs at least partially along at least one phase-encoding direction of the acquisition process;
a correlation unit configured to ascertain correlation information for each sequence segment of the plurality of sequence segments by comparison of the navigator dataset of the respective sequence segment with at least one navigator dataset of a further sequence segment of the plurality of sequence segments and the same k-space trajectory; and
an evaluation unit configured to evaluate the correlation information for selecting sequence segments of the plurality of sequence segments, the magnetic resonance data of which is to be discarded, assign a weighting to the magnetic resonance data of at least some of the sequence segments, or a combination thereof.

20. In a non-transitory computer-readable storage medium that stores instructions executable by one or more processors to operate a magnetic resonance facility in an acquisition process in accordance with an acquisition protocol that includes, in at least one repetition, a plurality of sequence segments of a magnetic resonance sequence, wherein each sequence segment of the plurality of sequence segments comprises a preparation module and a readout module, and each readout module comprises a plurality of readout submodules in which in each case radiofrequency pulses precede readout periods for the acquisition of magnetic resonance data, the instructions comprising:
acquiring navigator data of the respective sequence segment along a k-space trajectory using, in each readout module, at least one navigator submodule, wherein, for at least one pair of navigator submodules, the k-space trajectory used therein runs at least partially along at least one phase-encoding direction of the acquisition process;
ascertaining, for each sequence segment of the plurality of sequence segments, correlation information, the ascertaining comprising comparing a navigator dataset of the respective sequence segment with at least one navigator dataset of a further sequence segment of the plurality of sequence segments and the same k-space trajectory; and
evaluating the correlation information in order to select sequence segments of the plurality of sequence segments, the magnetic resonance data of which is discarded, to assign a weighting to the magnetic resonance data of at least some sequence segments of the plurality of sequence segments, or a combination thereof prior to reconstruction of a magnetic resonance image.
